(19) United States
(12) Patent Application Publication
(10) Pub. No.: US 2013/0250017 A1
(43) Pub. Date: Sep. 26, 2013

(54) RECORDING MEDIUM SURFACE PROPERTY MODIFYING APPARATUS, RECORDING MEDIUM, AND INKJET PRINTER SYSTEM

(71) Applicants: Haruki SAITOH, Miyagi (JP); Hijiri Ogata, Miyagi (JP); Takehiro Nakamura, Ibaraki (JP); Masaru Hoshina, Ibaraki (JP)

(72) Inventors: Haruki SAITOH, Miyagi (JP); Hijiri Ogata, Miyagi (JP); Takehiro Nakamura, Ibaraki (JP); Masaru Hoshina, Ibaraki (JP)

(21) Appl. No.: 13/843,470

(22) Filed: Mar. 15, 2013

(30) Foreign Application Priority Data
Mar. 23, 2012 (JP) 2012-067559

(51) Int. Cl. C23C 16/513; B41M 5/50; B41J 11/00; C23C 16/52

(52) U.S. Cl. CPC C23C 16/513; C23C 16/52; B41M 5/502; B41J 11/0015
USPC 347/101; 118/723 E; 118/708; 428/32.1

(57) ABSTRACT

A recording medium surface property modifying apparatus is disclosed. The recording medium surface property modifying apparatus includes a conveying unit which conveys a recording medium in a predetermined direction; a discharging electrode which rotates and comes into contact with a face to be treated of the recording medium which is conveyed by the conveying unit to cause the face to be treated to be in contact with plasma to modify a surface property of the recording medium; and a hollow-shaped cover member which covers a plasma treatment unit which includes the discharging electrode, the recording medium surface property modifying apparatus further including a humidity control unit which controls, in advance, humidity of the plasma treatment unit in alignment with acidity of the recording medium which undergoes the surface property modifying treatment.

### TECHNICAL FIELD

The present invention relates to apparatuses which modify a surface property of recording media such as a printing sheet, etc., which are used in image forming apparatuses such as an inkjet printer, etc., for example.

### BACKGROUND ART

A type of printing sheets used in image forming apparatuses such as an inkjet printer, etc., includes coat paper, which is a sheet for which a printing quality which is better than that of plain paper may be obtained by coating a predetermined coating material onto a surface of original paper (a base material). When ink droplets are caused to be impacted onto the coat paper with an inkjet printer, beading may occur. This beading is a phenomenon in which irregular gaps and density deviations, etc., occur due to neighboring ink dots connecting on a printing sheet, thereby damaging an image.

This beading is caused by a mismatch between ink properties and an ink receiving layer of the printing sheet, and is usually caused by a delayed ink absorption of the ink receiving layer of the printing sheet and neighboring ink droplets flowing to mix with one another, so that at least there is a need to suppress fluidity of ink droplets on the sheet. There is a related art case in which, when a sheet surface is subjected to a plasma discharging treatment, ink wettability is improved, fluidity of the ink droplets on the sheet is suppressed, and as a result, beading is also suppressed.

In Patent Document 1 is proposed a method of modifying a surface property of a recording medium by a plasma discharging treatment for a purpose of manufacturing the recording medium which has a high image receiving capability and in which an image is not disturbed even after receiving the image. More specifically, a plasma treatment is applied to a base material having an air gap structure for an image receiving layer thereof to hydrophilize a surface layer. In this way, a water absorbing capability of the recording medium in a thickness direction may be improved, an image receiving performance may be enhanced, and the side closer to the surface may be made water-repellent to make it possible to prevent disturbances after receiving an ink droplet image.

An atmosphere in which the plasma treatment is subjected to according to this surface property modifying method being at least 0.005 (kg-Water vapor/kg-Dry gas) in absolute humidity is disclosed in Patent Document 1.

### PATENT DOCUMENT

Patent Document 1: JP2000-301711A

However, there is a problem with the proposed method of modifying the surface property by the plasma discharging treatment as follows: While a high speed treatment is demanded in commercial printing which uses an elongated coat paper, a plasma treatment with a linear velocity of between 10 mm/sec and 30 mm/sec is needed before the surface property of the coat paper is modified, so that it takes a long treatment time, causing a high cost.

Methods of increasing a linear velocity of the plasma treatment include increasing an applying voltage for plasma generation and lining up multiple mechanisms for treating a recording medium to be treated to increase the number of times of treatment. While these methods are performed for an object of increasing plasma discharging energy for each unit area, it is not preferable from an efficiency point of view.

### DISCLOSURE OF THE INVENTION

An object of the present invention is to overcome the problems of the related-art and to provide an apparatus which modifies a surface property of a recording medium that may increase efficiency of a plasma treatment regardless of energy for each unit time of the plasma treatment.

According to an embodiment of the present invention, a surface property modifying apparatus is provided, including a conveying unit which conveys a recording medium in a predetermined direction; a discharging electrode which rotates and comes into contact with a face to be treated of the recording medium which has been conveyed by the conveying unit to cause the face to be treated to be in contact with plasma to modify a surface property of the recording medium; and a hollow-shaped cover member which covers a plasma treating unit which includes the discharging electrode, the surface property modifying apparatus further including a humidity control unit which controls, in advance, a humidity of the plasma treatment unit in alignment with acidity of the recording medium which undergoes the surface property modifying treatment.

The present invention makes it possible to provide an apparatus modifying a surface property of a recording medium that may increase efficiency in plasma treatment regardless of energy for each unit time of plasma treatment.

### BRIEF DESCRIPTION OF THE DRAWINGS

Other objects, features, and advantages of the present invention will become more apparent from the following detailed descriptions when read in conjunction with the accompanying drawings, in which:

FIG. 1 is a schematic configuration diagram of a recording medium surface property modifying apparatus according to Embodiment 1 of the present invention;

FIG. 2 is a characteristic diagram showing a relationship between an absolute humidity of atmosphere in a plasma treatment unit and a pH value of a treated printing sheet;

FIG. 3 is a schematic configuration diagram of the recording medium surface property modifying apparatus according to Embodiment 2 of the present invention;

FIG. 4 is a schematic configuration diagram of a first inkjet printer system to which is applied the recording medium surface property modifying apparatus according to embodiments of the present invention; and

FIG. 5 is a schematic configuration diagram of a second inkjet printer system to which is applied the recording medium surface property modifying apparatus according to embodiments of the present invention.

### BEST MODE FOR CARRYING OUT THE INVENTION

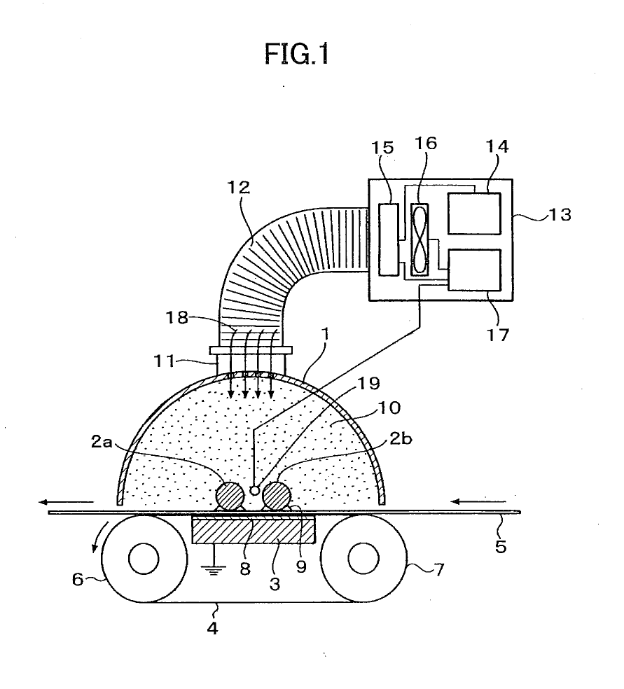

In conjunction with the drawings, a description is given in the following with regard to embodiments of the present invention. FIG. 1 is a schematic configuration diagram of a recording medium surface property modifying apparatus according to Embodiment 1 of the present invention.

An electrode cover 1 (shown) is a hollow-shaped electrode cover, an opening of a lower end of which is adjacent to and which opposes an upper face of an elongated recording medium 5 which includes roll paper, for example, which is conveyed. On a conveying path of the recording medium 5 are arranged two discharging electrode rollers 2a and 2b lined up and these two discharging electrode rollers 2a and 2b include metal rollers of the same shape.

Below the discharging electrode rollers 2a and 2b is arranged an endless dielectric belt 4 which also serves as a conveying unit of the recording medium 5; and the dielectric belt 4, which is wound between a drive roller 6 and a follower roller 7, circularly moves in a counterclockwise direction in FIG. 1 with a motor (not shown). A rotational speed of the motor may be adjusted to adjust a running speed of the dielectric belt 4, or in other words, a surface property modifying treatment speed of the recording medium 5.

Moreover, a counter electrode 3 which is configured with a flat plate of aluminum, etc., is arranged on an area opposing the discharging electrode rollers 2a and 2b that is a lower face of an upper-side horizontal portion of the dielectric belt 4. A glass layer 8, which is formed on an upper face of the counter electrode 3, functions as an insulating layer of the counter electrode 3. This counter electrode 3 is grounded. A width of the counter electrode 3 (a width in a direction which is vertical to a paper face) is formed shorter than a width of the dielectric belt 4.

Center axles of rotation of the discharging electrode rollers 2a and 2b extend in a width direction of the dielectric belt 4, and the two discharging electrode rollers 2a and 2b are arranged such that a virtual line which connects centers of rotation of the two discharging electrode rollers 2a and 2b becomes parallel to a moving face of the dielectric belt 4.

The respective discharging electrode rollers 2a and 2b are formed a little longer than the width of the dielectric belt 4, and a metal portion which is projected out of the dielectric belt 4 is exposed as it is, or is covered with a dielectric or an insulator. The discharging electrode rollers 2a and 2b are caused to be in contact with the dielectric belt 4 with a predetermined contact pressure by an elastic biasing means such as a compression spring (not shown), making it possible to handle the recording medium 5 of a different thickness that is conveyed between the discharging electrode rollers 2a and 2b and the dielectric belt 4. The respective discharging electrode rollers 2a and 2b, which are rotatably supported, are configured to rotate and be in contact with a face to be treated (an upper face) of the recording medium 5 in conjunction with conveying of the recording medium 5. Electrostatic charging of the dielectric belt 4 may be suppressed by the discharging electrode rollers 2a and 2b.

To the respective discharging electrode rollers 2a and 2b, a voltage is applied by a high-voltage power supply (not shown) in order to form plasma (atmospheric pressure non-equilibrium plasma) 9. The atmospheric pressure non-equilibrium plasma includes an atmospheric pressure plasma discharge, an atmospheric glow discharge, a corona discharge, a streamer discharge under atmospheric pressure, a creeping discharge, a dielectric barrier discharge, etc. Energy of generally between 102 mJ/cm² to 12674 mJ/cm² is provided to the respective discharging electrodes 2a and 2b.

The dielectric belt 4 has a width which is larger than that of various recording media 5 to be used, is configured with an insulator such as a polyimide resin sheet, for example, and has a surface layer with a value of resistance which is substantially insulating.

As a base material of the recording medium 5, a synthetic resin film such as polyethylene terephthalate, polyethylene naphthalate, polyethylene, polypropylene, etc., or paper may be used. The recording medium 5 is configured by forming, on both faces of the base material thereof, an image receiving layer (a functional layer) which is made of various materials. A plasma treatment can be applied to this image receiving layer to further improve an image receiving performance.

In order to provide hydrophilicity to the recording medium 5, water vapor (H₂O), alcohol, oxygen gas, carbon acid gas, etc., may be used as a reaction gas. In order to provide water repellency to the recording medium, a gas of a fluoride containing a compound such as carbon tetrafluoride, carbon hexafluoride, propylene hexafluoride, etc., may be used, for example, as a reaction gas. Then, as a gas other than the reaction gas, an inert gas such as argon, neon, helium, krypton, xenon, etc., is mixed thereto. These mixed gases are supplied to a plasma treatment unit 10, plasma discharging is performed in an atmosphere with atmospheric pressure or a pressure which is close thereto, an atmospheric pressure non-equilibrium plasma 9 generated by the respective discharging electrode rollers 2a and 2b is caused to be in contact with a face to be treated (an upper face) of the recording medium 5 to modify the surface property of the recording medium 5.

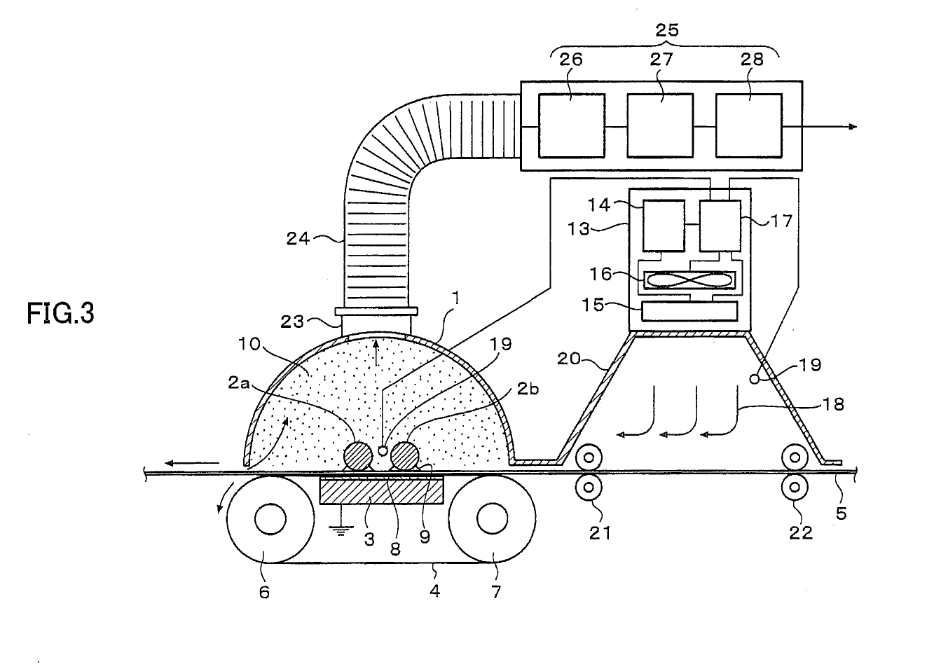

A moisturized air inlet 11 is provided at an upper portion or a side portion of the electrode cover 1 which covers a plasma treatment unit 10 including the discharging electrode rollers 2a and 2b, one end of a hose 12 is connected to the moisturized air inlet 11, and a moisture conditioning apparatus 13 for controlling humidity of the plasma treatment unit 10 is connected to the other end of this hose 12. This moisture conditioning apparatus 13 includes a water tank 14, a spraying nozzle 15, a blower fan 16, a control unit 17, etc. While the control unit 17 is drawn in FIG. 1 to be installed within the moisture conditioning apparatus 13 in order to describe an overall configuration of the moisture conditioning apparatus 13, there is a concern with an effect of moisture, so that it is also possible to install the control unit 17 outside the moisture conditioning apparatus 13. This also applies to a below-described recording medium surface property modifying apparatus shown in FIG. 3.

Fine water droplets (mist) are sprayed from the spraying nozzle 15 and the blower fan 16 is rotated, so that moisturized air 18 is produced, which produced moisturized air 18 is forced to be supplied to the plasma treatment unit 10 within the electrode cover 1 via the hose 12 and the moisturized air inlet 11. The control unit 17 controls a water spray amount of the spraying nozzle 15 such that the humidity within the electrode cover 1 (in the vicinity of the discharging electrode rollers 2a and 2b in particular) becomes a predetermined absolute humidity.

Moreover, a water spraying amount of the spraying nozzle 15 may be controlled such that the humidity within the electrode cover 1 (in the vicinity of the discharging electrode rollers 2a and 2b in particular) becomes a predetermined absolute humidity based on a feedback signal from a moisture detecting unit 19, which is installed in the vicinity of the discharging rollers 2a and 2b.

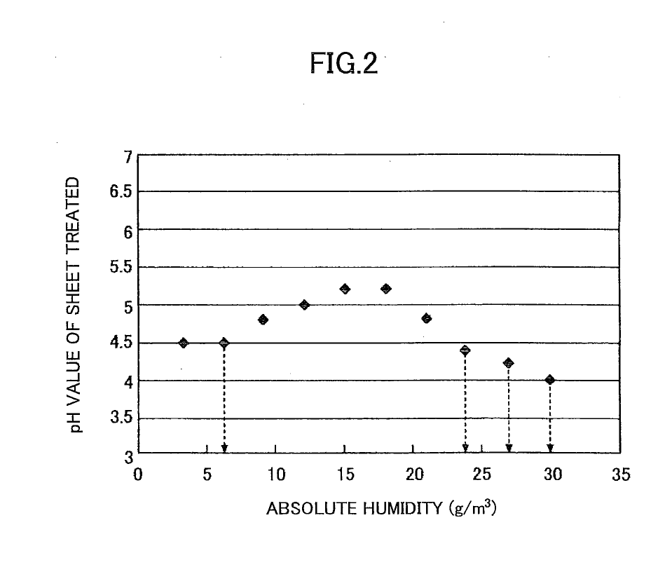

FIG. 2 is a characteristic diagram showing a relationship between absolute humidity of atmosphere in the plasma treatment unit 10 (in the vicinity of the discharging electrode rollers 2a and 2b) and a pH value of a plasma treated sheet, in which diagram an absolute humidity of the atmosphere is taken on a horizontal axis thereof and a pH value of the treated sheet is taken on a vertical axis thereof.

In this experiment, using Ricoh Business Coat Gloss 100 as a recording medium, a surface property of the recording medium was modified with plasma discharging conditions of 12 kVp-p for an applying voltage; 22 kHz for an output frequency; and 30 mm/s for a sheet linear velocity of plasma treatment.

Moreover, using a pH tester Pen S-5, which is manufactured by Nikken Chemical Laboratory, a sample was applied to the treated recording medium and a pH value of the sheet which underwent surface property modifying treatment was measured from color reaction by checking with a color sample.

The recording medium is caused to be in contact with discharge plasma, so that the recording medium surface is oxidized, so that the pH value is decreased. Then, in the discharge plasma, various active species occur such as atomic oxygen (.O), hydroxyl radical (.OH), ozone (O₃), etc.

As described above, in the related-art treatment method, as treatment efficiency is not high, it is necessary to perform treatment in low velocity of a plasma treatment linear velocity between 10 mm/s and 30 mm/s, so that it is necessary to produce more of the various active species to bring them in contact with the recording medium. On the other hand, according to the present invention, oxidization of the recording medium surface may be enhanced, so that, as a result, treatment efficiency may be improved.

More specifically, a pH value of the plasma treated recording medium surface may be decreased to equal to or below 4.5, and may preferably be decreased to equal to or below 4.2.

As is evident from FIG. 2, the absolute humidity may be controlled to be between 3 g/m³ and 6 g/m³, or to be 23 g/m³ in order to set the pH value of the treated recording medium surface in the vicinity of 4.5; the absolute humidity may be controlled to be 27 g/m³ in order to set the pH value of the treated recording medium surface to 4.2; and the absolute humidity may be controlled to be 30 g/m³ in order to set the pH value of the treated recording medium surface to 4.0.

However, in practice, when the absolute humidity within the plasma treatment unit 10 exceeds 30 g/m³, dewing condensation occurs, causing a danger of electric shock and making discharging not possible. Incidentally, for the absolute humidity of 24 g/m³, the relative humidity at a temperature of 30° C. becomes 80%. Therefore, in the present invention, in order to efficiently obtain oxidation of the recording medium 5 due to plasma discharging, the absolute humidity of the plasma environment is regulated to be less than or equal to 30 g/m³.

For coat paper for commercial printing (Ricoh Business Coat Gloss 100, for example), an effect of humidity on paper does not have to be taken into account so much. However, for plain paper, there is a possibility that an occurrence of jamming within an image processing apparatus due to an occurrence of wrinkling, such as due to absorption of moisture into the paper, etc., becomes a problem.

FIG. 3 is a schematic configuration diagram of the recording medium surface property modifying apparatus according to Embodiment 2 of the present invention. For the present embodiment, as shown in FIG. 3, a moisturizing unit cover 20, which has a hollow shape, is continuously provided in an integrated manner on the upstream side in a recording medium conveying direction of the electrode cover 1. An outer shape of the moisturizing unit cover 20 is almost a shape of a trapezoid, on an upper portion of which trapezoid or on a side face on the upstream side in the recording medium conveying direction is provided the moisture conditioning apparatus 13.

The moisture conditioning apparatus 13 includes a water tank 14, a spraying nozzle 15, a blower fan 16, a control unit 17, etc., where the control unit 17 controls a water spraying amount of the spraying nozzle 15 so that moisturized air 18 is supplied within the electrode cover 1 through inside the moisturizing unit cover 20 such that the humidity inside the electrode cover 1 and (or) the humidity inside the moisturizing unit cover 20 become a predetermined absolute humidity.

Moreover, as shown in FIG. 3, the humidity detecting units 19 are provided within the electrode cover 1 (in the vicinity of the discharging electrode rollers 2a and 2b in particular) and within the moisturizing unit cover 20, and, based on feedback signals from the moisture detecting units 19, the water spraying amount of the spraying nozzle 15 may be controlled such that inside the electrode cover 1 (in the vicinity of the discharging electrode rollers 2a and 2b in particular) and (or) inside the moisturizing unit cover 20 become a predetermined absolute humidity.

On a conveying path of the recording medium 5 that is on the lower end opening side of the moisturizing unit cover 20 are provided a driving roller pair 21 and a driven roller pair 22 that are for conveying the recording medium 5, and the driving roller pair 21 is arranged to rotate in synchronicity with the dielectric belt 4.

At an upper portion or a side portion of the electrode cover 1 is provided a gas discharging outlet 23, which is connected to a hose 24, which is connected to an ozone deodorizing apparatus 25. The ozone deodorizing apparatus 25 includes therein a catalytic layer 26; an adsorption layer 27; and an exhaust fan 28 from the upstream side to the downstream side in an exhaust gas flow direction.

In the catalytic layer 26 are loaded catalytic particles, such as particulate manganese dioxide, for decomposing high-density ozone. Moreover, in the adsorption layer 27 is loaded an adsorbent such as activated carbon, etc., for adsorbing low-density ozone, which could not be treated in the catalytic layer 26. Wind power of the exhaust fan 28 is set at a level such that ozone produced within the electrode cover 1 does not leak out.

The surface property modifying apparatus according to the present embodiment that is configured in this way controls the humidity within the electrode cover 1 (in the vicinity of the discharging electrode rollers 2a and 2b in particular) in accordance with a desired plasma treatment intensity or type of sheets.

More specifically, as shown in FIG. 2, when a pH value 4.2 is needed for the recording medium 5 which underwent the surface property modifying treatment, the spraying amount of the spraying nozzle 15 is controlled such that the absolute humidity in the vicinity of the discharging electrode rollers 2a and 2b becomes 27 g/m³. When a pH value of 4.5 suffices, the absolute humidity is controlled to be between 3 g/m³ to 6 g/m³ or to be 23 g/m³. As an output sheet, the high humidity side (between 21 g/m³ and 30 g/m³, for example) may be selected when coat paper for commercial printing (such as the Ricoh Business Coat Gloss 100, etc.) is used, while the low humidity side (between 3 g/m³ and 9 g/m³, for example) may be selected when Japanese paper, plain paper, etc., are used.

It is considered that atomic oxygen (.O), which is generated by discharging, contributes to a reaction with a sheet surface when the low humidity side is selected, while atomic oxygen (.O) reacts with water vapor (H₂O) to become hydroxyl radical (.OH), contributing to a reaction with a recording medium surface when the high humidity side is selected.

Then, as evident from results in FIG. 2, it is considered that humidity which is more than 9 g/m³ and less than 21 g/m³ deviates from an optimal state even with respect to generation of active species of either the low humidity side and the high humidity side, so that an effect of lowering a pH value is low.

The Japanese paper or plain paper, which is sensitive to humidity, may be plasma treated multiple times, setting the humidity to be between 3 g/m³ to 6 g/m³, for example. The number of times of plasma treatment based on the type of the recording medium or a desired pH value is controlled by the control unit 17.

After undergoing plasma treatment in a high-humidity environment, when seeking to change the type of the recording medium or to change the desired pH value from the acidic side to the neutral side immediately, it is necessary to set the atmosphere within the electrode cover 1 to low humidity. In this case, wind power of the exhaust fan 28 may be caused to be a strong wind, or the exhaust fan 28 may be operated for a certain period to eliminate moisture within the electrode cover 1. Driving of the exhaust fan 28 in conjunction with changing a type of the recording medium is controlled by the control unit 17.

In the above-described Embodiment 1, an extract fan is installed in the electrode cover 1 to be driven when changing from a high humidity environment to a low humidity environment as described above to force the moisture within the electrode cover 1 to be removed.

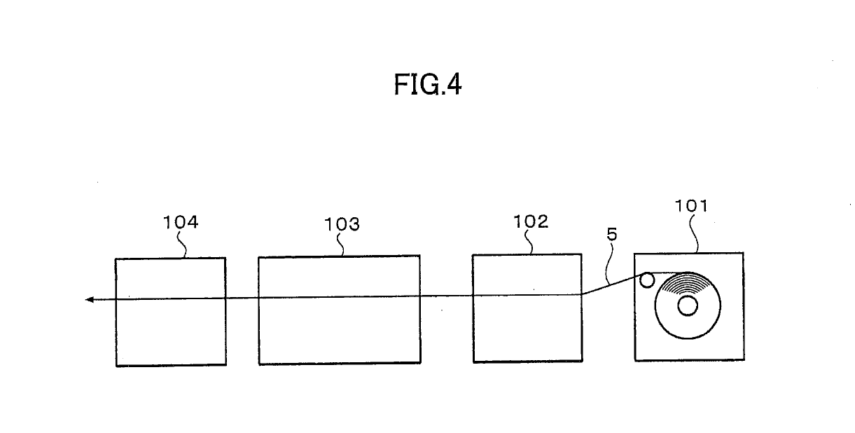

FIG. 4 is an overview configuration diagram of a first inkjet printer system to which the surface property modifying apparatus according to Embodiment 1 or 2 is applied.

As shown in FIG. 4, the first inkjet printer system, which mainly includes a paper feeding apparatus 101; a surface property modifying apparatus 102; an inkjet printer 103; and a post-treatment apparatus 104, is arranged to have a linked relationship as shown.

The recording medium 5, which has an elongated shape (a web shape), such as a roll paper, etc., that is sent out of the paper-feeding apparatus 101 is fed into the surface property modifying apparatus 102 in which a surface property modifying treatment of the recording medium 5, such as provision of hydrophilicity, provision of water-repellent properties, for example, is performed. A specific configuration within the surface property modifying apparatus 102 is similar to the surface property modifying apparatus as described in FIG. 1 or FIG. 3, so that repeated explanations are omitted.

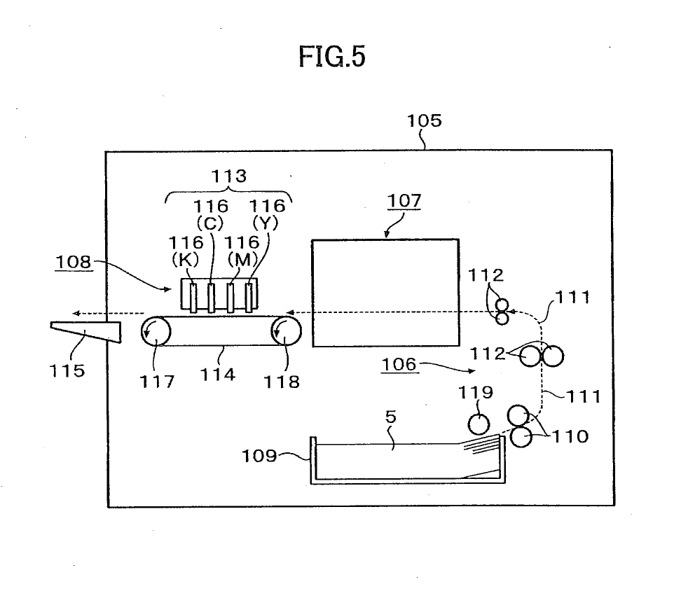

Next, the treated recording medium 5 is fed into the inkjet printer 103, ink droplets are jetted onto the surface of the recording medium 5 based on image information to be recorded, so that a desired color image is formed thereon. The image forming unit within the inkjet printer 103 will be described for a second inkjet printer system as shown in FIG. 5 in the following. Next, the recording medium 5, on which the image is formed, is arranged such that it is sent to a post-treatment apparatus 104, so that a predetermined post treatment is performed.

FIG. 5 is a schematic configuration diagram of a second inkjet printer system to which is applied the surface property modifying apparatus according to Embodiment 1 or 2 of the present invention.

As shown in FIG. 5, the ink inkjet printer system is collectively arranged in one image forming apparatus 105, which image forming apparatus 105 mainly includes a paper feeding unit 106, a surface property modifying unit 107, and an image forming unit 108.

In the paper feeding unit 106, a recording medium 5 having a shape of a sheet which is cut into a predetermined size is stacked and stored within the paper feeding tray 109, the recording medium 5, which is separated sheet by sheet, is sent to the surface property modifying unit 107 via multiple conveying roller pairs 112 while passing through the conveying path 111.

A specific configuration within this surface modifying unit 107 is the same as the surface property modifying apparatus described in FIG. 1 or FIG. 3, so that repeated explanations are omitted.

The image forming unit 108 mainly includes a recording head unit 113 which ejects ink droplets onto the recording medium 5 to form an image thereon; a conveying belt 114 which conveys the recording medium 5; and a paper discharging tray which contains the recording medium 5 on which an image is formed.

In the recording head unit 113 are arranged, along a conveying direction of the recording medium 5, four line-type ink ejecting heads 116 having nozzle columns (not shown) in which are aligned, in a length corresponding to a width of the recording medium 5, a large number of nozzles which eject ink droplets. These four ink ejecting heads 116 are ink ejecting heads 116(Y), 116(M), 116(C), and 116(K), which eject ink droplets of respective colors of yellow (Y), magenta (M), cyan (C), and black (K). As a serial image forming apparatus, it may be arranged for recording heads to be mounted in a carriage.

The conveying belt 114, which is an endless belt, is configured such that it is stretched across a conveying roller 117 and a tension roller 118 to go therearound. The recording medium 5 is held to the conveying belt 114 by electrostatic adsorption, adsorption by suction of air, etc.

The sheet-shaped recording medium 5, which is contained in the paper feeding tray 109, is separated sheet by sheet by a pickup roller 119, the separated sheet is supplied onto a conveying path 111 by the paper-feeding roller pair 110, and further sent to the surface property modifying unit 107 by multiple conveying roller pairs 112. In the surface property modifying unit 107 is performed a property modifying treatment onto a surface of the recording medium 5 (provision of hydrophilicity, provision of water-repellent properties, for example), and then the treated recording medium 5 passes under the recording head unit 113 due to an orbital movement of the conveying belt 114.

Then, from inkjet ejecting heads 116(Y), 116(M), 116(C), and 116(K), ink droplets of the respective colors are ejected onto the recording medium 5, so that a color image is formed, after which the recording medium 5 is dried to be discharged onto a paper-discharging tray 115.

The present application is based on Japanese Priority Application No. 2012-067559 filed on Mar. 23, 2012, the entire contents of which are hereby incorporated by reference.

1. A recording medium surface property modifying apparatus, comprising:
a conveying unit which conveys a recording medium in a predetermined direction;
a discharging electrode which rotates and comes into contact with a face to be treated of the recording medium which is conveyed by the conveying unit to cause the face to be treated to be in contact with plasma to modify a surface property of the recording medium; and
a hollow-shaped cover member which covers a plasma treatment unit which includes the discharging electrode, the recording medium surface property modifying apparatus further including a humidity control unit which controls, in advance, humidity of the plasma treatment unit in alignment with acidity of the recording medium which undergoes a surface property modifying treatment.

2. The recording medium surface property modifying apparatus as claimed in claim 1, further comprising:
a spraying nozzle which sprays liquid in order to adjust the humidity within the plasma treatment unit; and
a humidity detecting unit which detects the humidity within the plasma treatment unit, wherein a liquid spraying amount from the spraying nozzle is controlled based on a detected signal from the humidity detecting unit.

3. The recording medium surface property modifying apparatus as claimed in claim 2, wherein
the humidity detecting unit is provided in the vicinity of the discharging electrode.

4. The recording medium surface property modifying apparatus as claimed in claim 1, wherein
the humidity control unit is configured to control the humidity of the plasma treatment unit in accordance with a type of the recording medium.

5. The recording medium surface property modifying apparatus as claimed in claim 1, further comprising:
an exhaust unit which discharges moisture of the plasma treatment unit when the humidity control unit issues an instruction to change a humidity environment of the plasma treatment unit from a high humidity environment to a low humidity environment.

6. The recording medium surface property modifying apparatus as claimed in claim 5, wherein
an ozone deodorizing apparatus which includes the exhaust unit is installed in the plasma treatment unit and the exhaust unit also serves to discharge the moisture of the plasma treatment unit.

7. The recording medium surface property modifying apparatus as claimed in claim 1, wherein
the humidity control unit is arranged such that it may also control the number of times of the surface property modifying treatment in accordance with the type of the recording medium.

8. A recording medium for an inkjet printer, wherein a surface property modifying treatment is performed thereon by the recording medium surface property modifying apparatus as claimed in claim 1.

9. An inkjet printer system, comprising:
a recording medium supplying unit which supplies a recording medium;
a recording medium surface property modifying treatment unit which performs a surface property modifying treatment onto a surface of the recording medium which is supplied by the recording medium supplying unit; and
an image forming unit which ejects ink droplets using an inkjet recording head on the surface of the recording medium, onto which surface a surface property modifying treatment is performed by the recording medium surface property modifying treatment unit, wherein
the recording medium surface property modifying treatment unit is the recording medium surface property modifying apparatus as claimed in claim 1.
